(19) United States
(12) Patent Application Publication
(10) Pub. No.: US 2003/0227032 A1
(43) Pub. Date: Dec. 11, 2003

(54) Wiring design method of integrated circuit device, system thereof, and program product thereof

(75) Inventors: Takanori Nawa, Kasugai (JP); Toshikatsu Hosono, Kasugai (JP); Takashi Yoneda, Kasugai (JP)

Correspondence Address: STAAS & HALSEY LLP, SUITE 700, 1201 NEW YORK AVENUE, N.W., WASHINGTON, DC, 20005, US

(73) Assignee: Fujitsu Limited, Kawasaki (JP)

(21) Appl. No.: 10/361,679

(22) Filed: Feb. 11, 2003

(30) Foreign Application Priority Data
Jun. 7, 2002 (JP) 2002-166535

(51) Int. Cl. H01L 27/10

(52) U.S. Cl. 257/208

(57) ABSTRACT

An object of this invention is to provide a wiring design method of integrated circuit device capable of determining a layout without such a problem as congestion of wirings efficiently upon determination of the wiring layout in the integrated circuit device, system thereof and program product thereof. In the wiring design method for determining the route of wiring between a cell and another cell in the integrated circuit device, first, a region in which wirings are to be placed is divided vertically and horizontally (S102). Which divided regions each wiring should cross is determined (S103). The numbers of the wirings crossing the border of each divided region are equalized (S104). If the length of a side of each divided region is larger than a predetermined length (No in S105), that region is further divided (S102). If the length of a side of each region is smaller than the predetermined length, the route at that time is adopted as the rough wiring route of each wiring (S106).

### CROSS-REFERENCE TO RELATED APPLICATIONS

This application is based upon and claims the benefit of priority from each of the prior Japanese Patent Application No. 2002-166535 filed on Jun. 7, 2002, the entire contents of which are incorporated herein by reference.

### BACKGROUND OF THE INVENTION

1. Field of the Invention

The present invention relates to a wiring layout in the integrated circuit device and more particularly to a wiring design method of an integrated circuit device for determining a wiring layout capable of suppressing generation of an operating error resulting from coupling capacity between wirings, system thereof and program product thereof.

2. Description of the Related Art

When the wiring layout in the integrated circuit device is determined, it must be considered that the wiring length is as short as possible in order to suppress the delay time of a signal as short as possible. Another request is to avoid congestion of wirings to a particular region if possible. If the wirings are congested, there is a fear that an operating error may be generated due to crosstalk noise because the coupling capacity between wirings at that position is large.

Thus, conventionally the wiring layout was determined as follows. First, the route of each wiring is determined so as to obtain a short wiring length. After the determination, crosstalk noise and the quantity of the change of a delay time due thereto are calculated according to its determination data. If a wiring having crosstalk noise or the quantity of change of delay time exceeding an allowable value is found, a corresponding post-problem is taken. As the measures, change of a wiring route, insertion of a stable potential wiring (e.g. power supply line) in between parallel wirings, insertion of a buffer into a divided position obtained by dividing the parallel wiring and the like can be mentioned. The change of the wiring route is a countermeasure for reducing the coupling capacity by enlarging the interval between adjacent wirings. The insertion of the stable potential wiring is a countermeasure for reducing an interaction by screening between the parallel wirings from each other. The insertion of the buffer is a countermeasure for reducing the coupling capacity by shortening the parallel portion of the wirings.

However, the above-described conventional technology has the following problems. That is, post-problem measures for the wiring having a crosstalk noise or a change value of the delay time exceeding their allowable value is not so simple work. The reason is that the routes of other wirings than a wiring to be corrected are already fixed. For that reason, even if it is intended to change the route of a wiring to be corrected, a place (channel) for that purpose often cannot be obtained. The same thing can be said of a case where it is intended to insert a stable potential wiring or a buffer. Further, even if such measures are taken successfully, a new problem may occur other places. Thus, there has been needed such a complicated processing as retrial for determining the wiring route from the beginning.

### SUMMARY OF THE INVENTION

Accordingly, it is an object of the present invention to provide a wiring design method of an integrated circuit device, system and program product thereof capable of efficiently determining wiring layout of an integrated circuit device that is free from problems such as congestion of wirings or the like.

To achieve the object, according to first aspect of the present invention, there is provided a wiring design method for determining wiring routes between cells of an integrated circuit device, the wiring design method comprising: region-divide step where a wiring-arrangement-target region is divided in both vertical and horizontal directions; rough-arrange step where, divided regions for wiring arrangement is determined with respect to each of wirings out of the wiring-arrangement-target region divided in the region divide step; and rearrange step where an alternative divided region for wiring arrangement is determined again in case wiring distribution among divided regions determined in the rough-arrange step is not uniform; wherein wiring routes are determined within determined divided regions.

In the first aspect of the present invention, for determining wiring routes between cells of an integrated circuit device, rough arrangement of wirings is carried out in accordance with the following steps. Firstly, a wiring-arrangement-target region is divided in both vertical and horizontal directions. Next, it is determined which divided regions each wiring should be arranged on. In case arrangement of wirings is not uniform, rearrangement of wirings is conducted. Accordingly, at the stage of determining rough wiring arrangement, congestion of wirings on a certain region can be avoided. Thereby, wiring layout of an integrated circuit device can be efficiently determined without problems such as congestion of wirings or the like.

Furthermore, according to second aspect of the present invention, there is provided a wiring design method for determining wiring routes between cells of an integrated circuit device, the wiring design method comprising: region-divide step where a wiring-arrangement-target region is divided in both vertical and horizontal directions; rough-arrange step where, divided regions for wiring arrangement is determined with respect to each of wirings out of the wiring-arrangement-target region divided in the region divide step; noise-estimate step where a maximum value of crosstalk noises is estimated based on determined wiring arrangement; and countermeasure step where crosstalk noises are reduced with respect to a wiring whose maximum value estimated at the noise predict step exceeds a predetermined value, wherein wiring routes are determined within determined divided regions.

In the second aspect of the present invention, a maximum value of crosstalk noises to occur is estimated with respect to each wiring after a wiring-arrangement-target region is divided in both vertical and horizontal directions and rough arrangement of wirings is determined. Therefore, large crosstalk noises caused by congestion of wirings can be forecasted. In case the estimated crosstalk noise quantity exceeds a predetermined value, a countermeasure is taken. Wiring design is not yet fixed at this stage, so it is easy to take such a countermeasure.

According to third aspect of the present invention, there is provided a wiring design system for determining wiring routes between cells of an integrated circuit device comprising: region-divide unit for dividing a wiring-arrangement-target region in both vertical and horizontal directions; rough-arrange unit for determining divided regions of the wiring-arrangement-target region on which each of wirings should be arranged; and rearrange unit for determining an alternative divided region on which a wiring should be arranged in case wiring distribution among divided regions determined in the rough arrange step is not uniform; wherein wiring routes are determined and arranged within determined divided regions.

Furthermore, according to fourth aspect of the present invention, there is provided a wiring design system for determining wiring routes between cells of an integrated circuit device comprising: region-divide unit for dividing a wiring-arrangement-target region in both vertical and horizontal directions; rough-arrange unit for determining a divided region of the wiring-arrangement-target region on which each of wirings should be arranged; noise-estimate unit for estimating a maximum value of crosstalk noises based on determined wiring arrangement; and countermeasure unit for reducing crosstalk noises with respect to a wiring whose maximum value estimated at the noise-estimate unit exceeds a predetermined value, wherein wiring routes are determined and arranged within determined divided regions.

Still further, according to fifth aspect of the present invention, there is provided a computer program product used for executing wiring design of an integrated circuit device by a computer, the computer program product comprising: a computer readable medium; and a computer program stored on the computer readable medium, the computer program comprising: region-divide step for dividing a wiring-arrangement-target region in both vertical and horizontal directions and assigning identification information to each of divided regions; rough-arrange step for determining rough arrangement of each wiring defined in accordance with order that a wiring passes over divided regions divided in the region-divide step; ununiformity-judge step for judging whether or not wiring distribution along with rough arrangement determined in the rough-arrange step has uniformity exceeding acceptable degree; and rearrange step for determining again other way of rough arrangement of wirings in case wiring distribution is determined as exceeding the acceptable degree of ununiformity in the ununiformity-judge step.

When the program of this program product is executed, the program instructs the computer to divide over a region for wiring arrangement and to assign identification information to each divided region. Next, the program instructs the computer to determined rough arrangement of each of wirings. In case distribution of wirings is not uniform, rough arrangement is determined again, whereby congestion of wirings can be avoided.

According to sixth aspect of the present invention, there is provided a computer program product used for executing wiring design of an integrated circuit device by a computer, the computer program product comprising: a computer readable medium; and a computer program stored on the computer readable medium, the computer program comprising: region-divide step for dividing a wiring-arrangement-target region in both vertical and horizontal directions and assigning identification information to each divided region; rough-arrange step for determining rough arrangement of each wiring defined in accordance with order that a wiring passes over divided regions divided in the region-divide step; noise-estimate step for estimating a maximum value of crosstalk noises based on determined wiring arrangement; and countermeasure step for changing rough arrangement or assigning limitation information with respect to wiring whose maximum value estimated at the noise estimate step exceeds a predetermined value.

When the program of this program product is executed, the program instructs the computer to determine rough arrangement of wirings and to estimate a maximum value of noise with respect to each wiring. In case the maximum value of the noise exceeds a predetermined value, the program instructs the computer to take countermeasure to change the rough arrangement or to assign limitation information to the wiring that has noise exceeding the predetermined value. Rough arrangement of wirings is changed to another way of rough arrangement so that a maximum value of noise should not exceed the predetermined value. Alternatively, limitation information is assigned to the wiring noise of which exceeds the predetermined value so that the limitation information should be used to make noise small when detailed arrangement of wirings is determined.

As apparent from the above description, the present invention realizes a wiring design method of an integrated circuit device, system and program product thereof capable of efficiently determining wiring layout of an integrated circuit device that is free from problems such as congestion of wirings or the like.

The above and further objects and novel features of the invention will more fully appear from the following detailed description when the same is read in connection with the accompanying drawings. It is to be expressly understood, however, that the drawings are for the purpose of illustration only and are not intended as a definition of the limits of the invention.

### BRIEF DESCRIPTION OF THE DRAWINGS

FIG. 1 is a diagram showing cell arrangement and connection relation among cells;

FIG. 2 is a diagram showing state that respective cells in FIG. 1 are tentatively connected;

FIG. 3 is a diagram showing first step to determine wiring routes;

FIG. 4 is a diagram showing second step to determine wiring routes;

FIG. 5 is a diagram showing an example of rough wiring routes;

FIG. 6 is a diagram showing an example of rough wiring routes;

FIG. 7 is a concise circuit diagram of crosstalk-noise-quantity calculation;

FIG. 8 is a model diagram of crosstalk-noise-quantity calculation;

FIG. 9 is a flow chart showing determination process of rough wiring routes;

FIG. 10 is a flow chart showing noise-quantity calculation process;

FIG. 11 is another flowchart showing noise-quantity calculation process;

FIG. 12 is another model diagram of crosstalk-noise-quantity calculation; and

FIG. 13 is still another model diagram of crosstalk-noise-quantity calculation.

### DETAILED DESCRIPTION OF THE PREFERRED EMBODIMENTS

Hereinafter, the preferred embodiments of the present invention will be described in detail with reference to the accompanying drawings. This embodiment aims at embodying the present invention as a method for determining the wiring layout in the integrated circuit device on a CAD system.

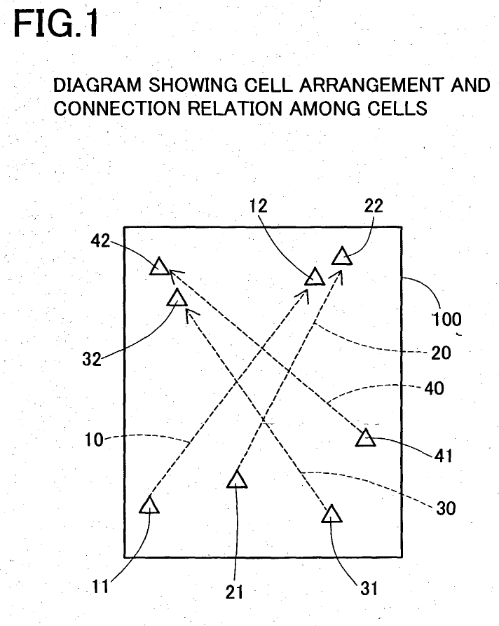

The method of this embodiment is applied at a stage in which the allocation of cells is determined in designing of the integrated circuit device. That is, on this stage as shown in FIG. 1, four driver cells 11, 21, 31, 41 and corresponding receiver cells 12, 22, 32, 42 are disposed in a frame 100. The positions of the respective cells are determined. The relations of connections of the respective cells by wirings are already determined. That is, the cell 11 and the cell 12 are connected through a wiring 10. The cell 21 and the cell 22 are connected through a wiring 20. The cell 31 and the cell 32 are connected through a wiring 30. Further, the cell 41 and the cell 42 are connected through a wiring 40. Although the wirings 10-40 in FIG. 1 are drawn with a straight line, this only indicates a connecting relation between the cells and thus, the wirings are not actually disposed linearly. The frame 100 indicates an outer frame of a region that can be used for allocation of the wirings 10-40 in the semiconductor chip. Each cell is a single element constituting the integrated circuit or a group thereof (gate array, standard cell and the like).

This method is a method for determining each wiring route that generates no error due to crosstalk noise with this stage as a starting point, while the respective wirings 10-40 are fixed with the shortest distance. Although theoretically the shortest distance is realized with a straight route connecting a cell to another cell, such an oblique wiring cannot be set up in an actual integrated circuit. The reason is that each wiring is provided along grids disposed finely in vertical and horizontal directions within the frame 100.

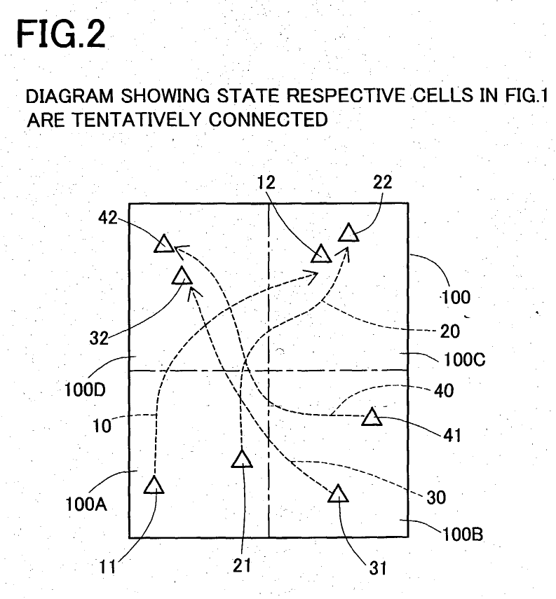

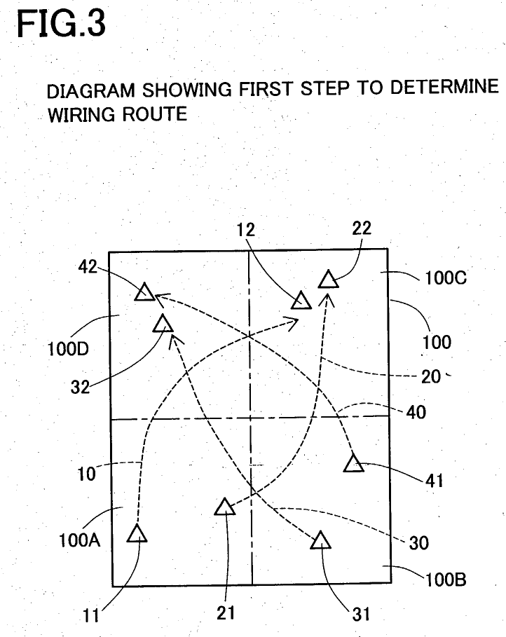

According to this method, first, the frame 100 in which the allocation of the cells 11-42 is determined is divided into four regions as indicated with a dot-dash line shown in FIGS. 2, 3. Then, which regions each wiring 10-40 crosses are determined. Consequently, the respective wirings 10-40 connecting the respective cells 11-42 are formed such that they cross the divided borders in various directions. The curve of each of the wirings 10-40 shown in FIGS. 2, 3 indicates only the divided region which each wiring crosses and the order of crossing those regions. Thus, it doesn't predetermine the actual positions where wirings 10-40 are disposed. That is, FIG. 2 shows that the wirings 10, 20 cross the region 100A, the region 100C and the region 100D in this order while the wirings 30, 40 cross the region 100B, the region 100A and the region 100D in this order. On the other hand, FIG. 3 shows that the wiring 10 crosses the region 100D, the wiring 20 crosses the region 100B, the wiring 30 crosses the region 100A and the wiring 40 crosses the region 100C.

The wirings 10-40 shown in FIG. 2 are deflected to the left half within the frame 100. Although the region 100C and the region 100B are crossed by only two wirings, the region 100A and the region 100D are crossed by four wirings. Thus, although the wiring which crosses the border between the region 100B and the region 100C is 0, the wirings which cross the border between the region 100A and the region 100D are four. If the allocation of the wirings is determined finally, the gap between the wirings in the left region of the frame 100 is small, so that the coupling capacity may be increased.

Then, the regions which the respective wirings 10-40 cross are determined again so that the number of the wirings 10-40 crossing the divided borders is as equal as possible while congestion of the wirings 10-40 is avoided. As a result of the treatment performed on FIG. 2, the respective wirings 10-40 shown in FIG. 3 are obtained. Although the number of the respective wirings 10-40 crossing the border vary from 4 to 0 in FIG. 2, the number of the respective wirings 10-40 crossing the border is two each in FIG. 3. Consequently, the number of the respective wirings 10-40 crossing the respective divided regions can be substantially equalized, generation of a space having a small gap between wirings can be avoided.

At this time, if both cells to be connected are located within the same divided region, that wiring is not taken into account. If a wiring crosses only a vertical border or a horizontal border, the route of that wiring is adopted because there is no other choice to ensure the shortest distance. Then, only the routes of the wirings which cross both the vertical and horizontal borders are changed so as to make the allocation of the respective wirings 10-40 as uniform as possible.

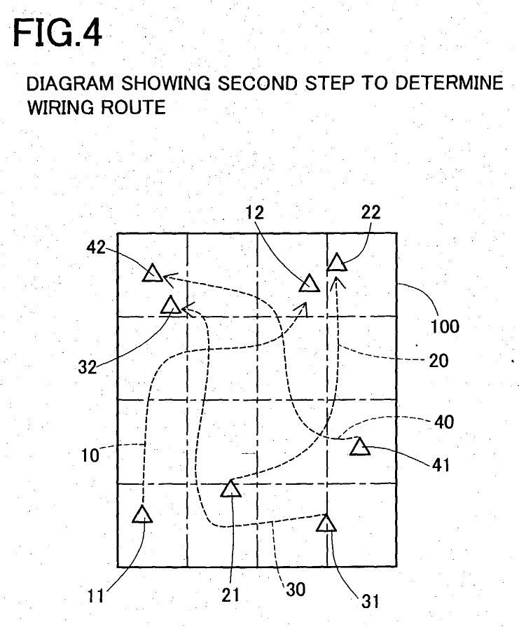

If the respective wirings 10-40 are disposed uniformly in each of regions divided into four equal sections, each region obtained by that division is further divided into four sections. Consequently, as shown in FIG. 4, the entire frame 100 is divided into 16 sections. At this time, the wiring not considered at the previous division may be taken into consideration object due to that further division. Likewise, the allocation of the routes is determined so that the number of the wirings crossing each border are as equal as possible. Consequently, the respective wirings 10-40 shown in FIG. 4 are obtained.

Although in FIGS. 1-4, four pairs of the cells and the wirings are indicated, an actual integrated circuit is provided with more cells and wirings. Therefore, a region obtained by dividing to 16 sections is too large and this division is not sufficient for-determining the wiring routes roughly. Further, this dividing procedure is repeated so as to divide each region to four sections, so that the numbers of the wirings crossing the border line are equalized. Then, this procedure is repeated until a side of each region obtained by the division becomes smaller than a predetermined value (length of about 10-20 grids). Each region when the division is finished with this side below the predetermined value is described as G-unit. At this stage, only the G-unit which each wiring crosses is determined and an actual wiring route is not yet determined.

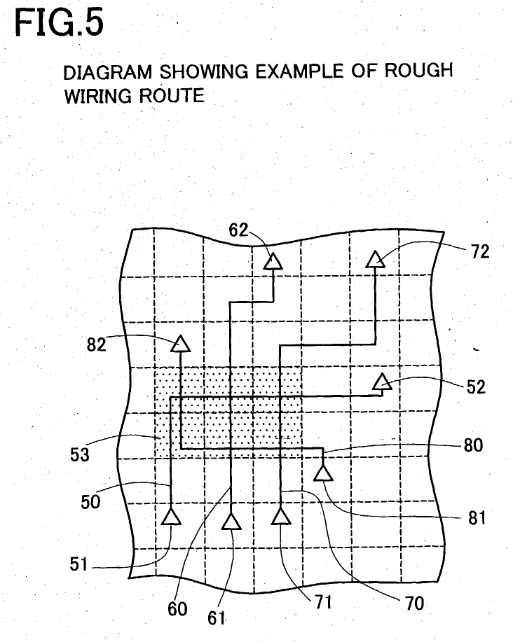

If G-units, which all the wirings cross are determined, next, crosstalk noise quantity is calculated by expectation. FIG. 5 shows the state in which the G-units which all the wirings cross are determined. This is a different example from the examples shown in FIGS. 1-4 while it indicates part of the frame 100. FIG. 5 shows four driver cells 51, 61, 71, 81 allocated within this range, corresponding four receiver cells 52, 62, 72, 82 and the rough routes of the wirings 50, 60, 70, 80. The border of each G-unit is indicated with dotted line.

The total number of the G-units, which the respective wirings 50-80 cross (including the end units of the respective wirings) and the number of the G-units shared by other wirings are counted. In FIG. 5, a hatched region indicates a shared G-unit which plural wirings cross. The number of the G-units which the respective wirings 50-80 cross is as follows.

As for the Wiring 50

Number of the G-units crossed=8, number of shared G-units=4

As for the Wiring 60

Number of the G-units crossed=8, number of shared G-units=2

As for the Wiring 70

Number of the G-units crossed=9, number of shared G-units=2

As for the Wiring 80

Number of the G-units crossed=7, number of shared G-units=4

From this result, the ratio of the number of the shared G-units with respect to the number of the G-units which each wiring crosses can be obtained. Generally, when this ratio is small, it can be said that there is little fear that a noise error may occur. Here, its threshold value is treated as 1/4. In this example, for the wirings, 50, 80, the ratio exceeds 1/4. Therefore, the crosstalk amount needs to be calculated by expectation.

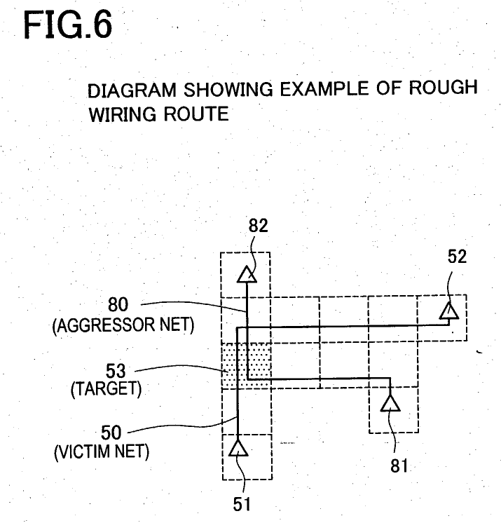

Next, a method for calculating the maximum crosstalk amount by expectation will be described about the wiring 50. The wiring 50 cross four shared G-units. Therefore for each shared G-unit, a model for noise calculation is prepared to calculate noise amount by expectation. As shown in FIG. 6, one of the shared G-units which the wiring 50 crosses is set to a target G-unit 53. Then, the wiring (here, the wiring 50) which an attention is paid to now is defined as “victim net” while another wiring (here, wiring 80) which crosses the target G-unit 53 is defined as “aggressor net”. If there are plural wirings which cross the target G-units 53 at this time, the wiring whose output slew-rate is the steepest is defined as “aggressor net”. Alternatively, according to other method, the net having a cell whose output driving performance is the highest is selected as the aggressor net. Then, noise quantity which the victim net receives from the aggressor net is calculated. Consequently, the noise quantity from a main noise source can be calculated.

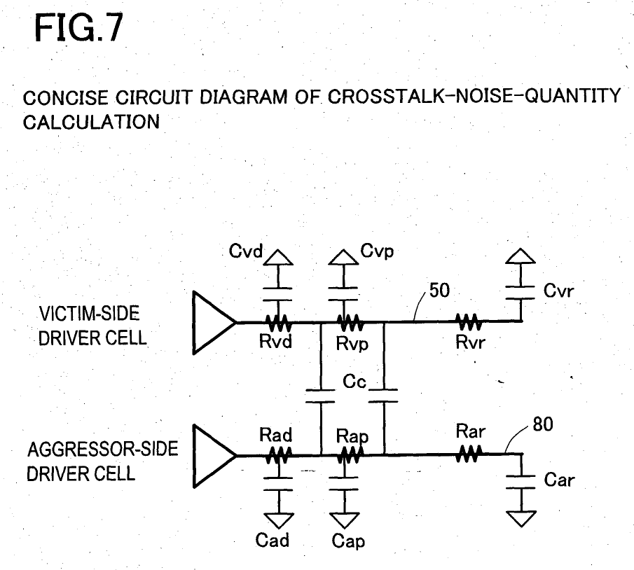

The noise calculation simple circuit model of the target G-unit 53 shown in FIG. 6 is created as shown in FIG. 7. The wirings 50, 80 have wiring resistance and wiring capacity at the G-unit groups on each side of the driver and receiver while the shared G-unit portion has the wiring resistance, wiring capacity and coupling capacity. In FIG. 7, the victim net is expressed with the suffix “v” and the aggressor net is expressed with the suffix “a”, while the driver side, the receiver side and the shared portion are expressed with the suffixes “d”, “r”, “p” respectively. Therefore, the capacity and resistance of the driver side wiring of the victim net are expressed as Cvd, Rvd. The capacity and resistance of the wiring in the shared G-unit are expressed as Cvp, Rvp. The capacity and resistance of the receiver side wiring are expressed as Cvr, Rvr. Likewise, for the aggressor net the capacity and resistance of the driver side wiring are expressed as Cad, Rad. The capacity and resistance of the shared G-unit wiring are expressed as Cap, Rap. Further, the capacity and resistance of the receiver side wiring are expressed as Car, Rar. The coupling capacity is expressed as Cc.

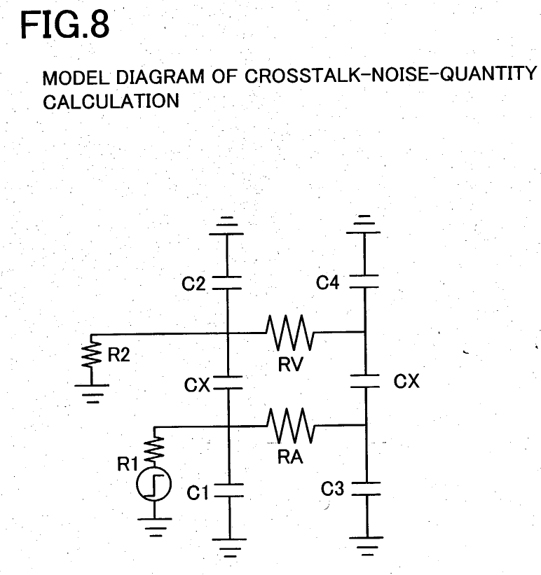

Next, as an equivalent model of this noise calculation simple circuit model, the π-Cx-π model is created. Here, the side in which R1 is connected corresponds to the aggressor net while the side in which R2 is connected corresponds to the victim net. Each capacity described in the model of FIG. 8 is obtained as follows.

C1 is the driver side capacity of the aggressor side and is obtained by Cap/2.

C2 is the driver side capacity of the victim side and is obtained by Cvd+Cvp/2.

C3 is the receiver side capacity of the aggressor side and is obtained by Car+Cap/2.

C4 is the receiver side capacity of the victim side and is obtained by Cvr+Cvp/2.

Cx is 1/2 the coupling capacity and is obtained by Cc/2.

Each resistance is obtained as follows.

RA is the shared portion resistance of the aggressor side and is equal to Rap.

RV is the shared portion resistance of the victim side and is equal to Rvp.

R1 is the driver side resistance of the aggressor side and is obtained by (driving resistance value of the aggressor side cell)+Rad. Or, this may be obtained as a driving resistance value up to the coupling start point. The driving resistance value of the aggressor side may be corrected corresponding to a waveform correspondence model of the aggressor side. R2 is the driver side resistance of the victim side and is obtained by (output resistance of the victim side cell)+Rvd. The output resistance of the victim side cell may be obtained by calculation from the output driving resistance with a correction coefficient. A noise peak value Vp is obtained from the equivalent model obtained in such a way according to equation 1. Further, a noise half width Tw is obtained according to equation 2.

$$\begin{matrix}{V}_{P} = \frac{C \times ( 2 R2 + RV ) \times VD}{R1 ( C1 + C3 + 2 CX ) + R2 ( C2 + C4 + 2 CX ) + RA ( C3 + CX ) + \\ RV ( C4 + CX ) - \frac{R2 \times RV}{2 R2 + RV} ( C2 + C3 + 2 CX )} & [ Equation 1 ] \\ {V}_{P} = R1 ( C1 + C3 + 2 CX ) + R2 ( C2 + C4 + 2 CX ) + \\ RA ( C3 + CX ) + RV ( C4 + CX ) - \frac{R2 \times RV}{2 R2 + RV} ( C2 + C3 + 2 CX ) & [ Equation 2 ]\end{matrix}$$

If R1, RA, C1, C3 are minimum to expect a case where an influence by the aggressor net is the most serious, the noise peak value Vp can be obtained according to equation 3 while the noise half width Tw can be obtained according to equation 4.

$$\begin{matrix}{V}_{P} = \frac{C \times ( 2 R2 + RV ) \times VD}{R2 ( C2 + C4 + 2 CX ) + RV ( C4 + CX ) - \frac{R2 \times RV}{2 R2 + RV} ( C2 + 2 CX )} & [ Equation 3 ] \\ {T}_{W} = R2 ( C2 + C4 + 2 CX ) + RV ( C4 + CX ) - \frac{R2 \times RV}{2 R2 + RV} ( C2 + 2 CX ) & [ Equation 4 ]\end{matrix}$$

These equations have been described in Ashok Vittal, Lauren Hui Chen, Malgorzata Marek-Sadowska, Kai-Ping, Sherry Yang “IEEE Trans, Computer-Aided-Design, vol.18, No.12, December 1999”. The noise quantity obtained this way is calculated for all the shared G-units of the wiring 50. Then, the obtained noise quantities are summed up. Consequently, the entire crosstalk amounts of a target wiring 50 can be estimated.

The estimated crosstalk amount obtained here is a theoretically maximum crosstalk amount which a target victim net may receive. Therefore when an actual wiring layout is created, no noise exceeding this estimated crosstalk amount occurs. Then, the estimated crosstalk amount is compared with an error judgment value. This error judgment value is a upper limit noise value having no fear of generating an error and preliminarily set up and stored. That is, if the total sum of the estimated noise quantity does not exceed the error judgment value about each victim net, it is found that there is no fear of generating an error due to the crosstalk in this rough wiring route. Therefore, it means that a pattern may be created at any place within each G-unit.

On the other hand if the total sum of the calculated crosstalk amount exceeds the error judgment value, it means that there is a fear of generating an error. Then, in this case, the rough wiring route of that wiring is corrected. For example, a portion of the wiring which crosses the shared G-unit having the maximum calculation value of the noise quantity is transferred to a G-unit adjacent to that shared G-unit. Then, the crosstalk amount is calculated again and error determination is carried out. Moving of the route and calculation of the noise quantity are repeated until the wiring route having no fear of error generation is found out.

As a result of this procedure, the G-units which all the wirings cross are determined so that the crosstalk amount of each wiring does not exceed the predetermined error judgment value. Then, finally, an actual wiring layout is created so that the wiring crosses the determined G-units in succession. According to this method, congestion of the wirings can be avoided at a rough wiring determination stage and further, an approximate noise quantity can be calculated before the actual wiring layout is created. Therefore, because there is no necessity of changing the wiring route each time after all the wiring routes are determined, the wiring layout can be determined efficiently.

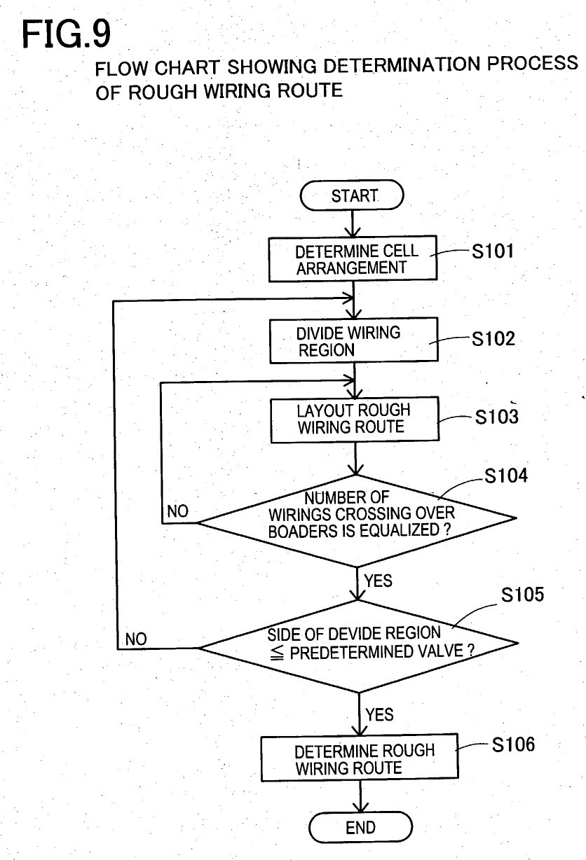

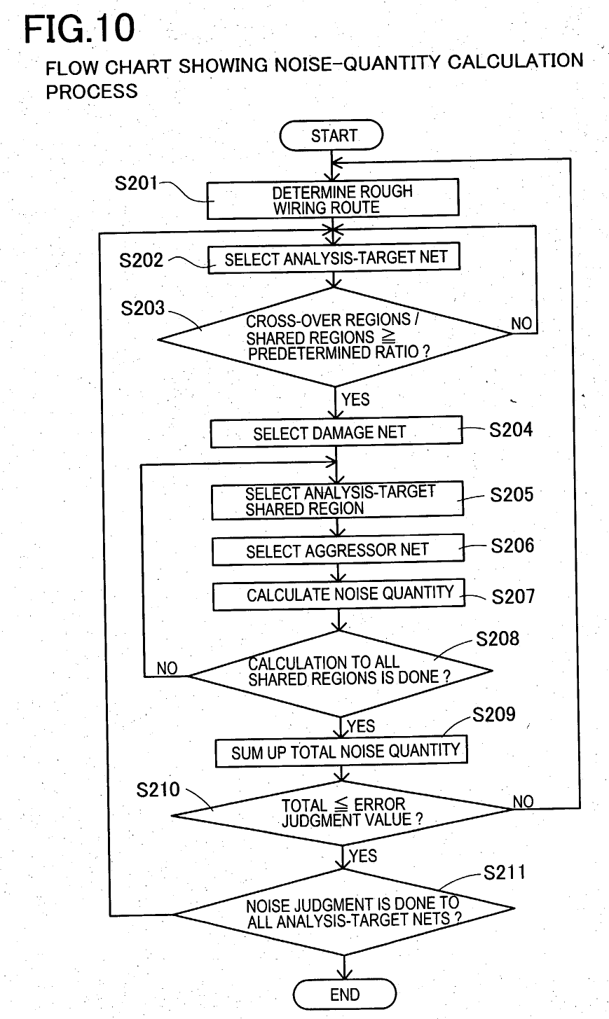

Next, the procedure for designing the wiring on a CAD system using the above-described method will be described with reference to flow charts shown in FIGS. 9 and 10. FIG. 9 is the flow chart of a program for a rough wiring route until the G-units which respective wiring cross are determined. FIG. 10 is the flow chart of a program for checking whether or not a calculated noise quantity is within its allowable range after the rough wiring route is determined.

First, the method for determining the rough wiring route will be described with reference to FIG. 9. According to this program, first, the allocation of respective cells and their connecting relation are determined (S101). FIG. 1 shows this stage. The wiring design procedure begins from here. Next, the frame 100 which is a wiring region in which wiring routes are to be set up is divided into four regions (S102). Then, each divided region is provided with a symbol for identification. In the example of FIG. 2, the symbols “100A”, “100B”, “100C”, and “100D” are attached. Then, the rough wiring route for connecting respective cells is determined as the order of the divided regions which a wiring crosses (S103). For example, for the wiring 20, two ways can be considered: route “100A-100B-100C” and route “101A-100D-100C”. One of them is selected. For other wirings, one of possible routes is selected likewise.

After all the rough wiring routes are determined, whether or not the numbers of wirings which cross each border of each divided region are substantially equal is checked (S104). If the disparity (difference between the maximum value and the minimum value) in the numbers of the wirings crossing respective borders is not within the allowable range (No in S104), the rough wiring placing is executed again (S103). Consequently, the state shown in FIG. 2 is changed to the state shown in FIG. 3.

If the numbers of the wirings crossing each border are equalized (Yes in S104), the length of a side of the divided region is checked (S105). If the length of a side of the divided region is larger than a predetermined value (No in S105), the wiring region is further divided (S102). Then, the procedure for rough wiring route (S103) and the equalization of the numbers of the wirings (S104) is carried out. As a result, the state shown in FIG. 4 is reached. If the length of a side of the divided region is less than the predetermined value (Yes in S105), the rough wiring route at that time is finally determined (S106) and this processing is terminated.

Next, the check method for the noise quantity will be described with reference to FIG. 10. According to this program, first, the rough wiring route shown in FIG. 9 is determined (S201). FIG. 5 shows this state. Next, nets of an analysis target are selected in succession (S202). Then, the ratio of the number of the shared G-units with respect to the number of the G-units which a selected net crosses is calculated. If the ratio of the shared G-units relative to the number of the crossing-over G-units is lower than the predetermined value (No in S203), the crosstalk amount of that net does not have to be calculated and therefore, a next net is selected (S202).

On the other hand, for the net whose ratio of the shared G-units exceeds the predetermined value (Yes in S203), its crosstalk noise quantity needs to be calculated. Then, this analysis-target net is regarded as a victim net (S204). For that victim net, the shared G-units of the analysis target are selected in succession (S205). An aggressor net in this shared G-unit is selected (S206). In the example shown in FIG. 6, the victim net is wiring 50, the shared G-unit of analysis target is target G-unit 53 and the aggressor net is the wiring 80.

FIG. 7 shows a simple circuit model based on the example 6. FIG. 8 is a diagram of an equivalent model based on the simple circuit model of FIG. 7. The aforementioned equations 1 and 2 or 3 and 4 are calculated using resistances and capacitances of this model diagram. Consequently, the noise quantity in the shared G-unit is calculated (S207). Then, whether or not the calculation on the noise quantity of all the shared G-units is completed is determined for a current target victim net (S208). If the calculation is not terminated (No in S208), the noise quantity is calculated likewise for the next shared G-unit (S205-S207).

If calculation on the noise quantities of all the shared G-units is completed about the target victim net (Yes in S208), the calculated noise quantities are summed up (S209). This sum result is compared with a predetermined error judgment value (S210). If it is determined that the sum result exceeds the error judgment value (No in S210), there is a possibility that noise error may occur. In this case, the rough wiring route of that victim net is changed and a new rough wiring route is determined (S201). Then, respective processings following S202 are carried out about the corrected rough wiring route.

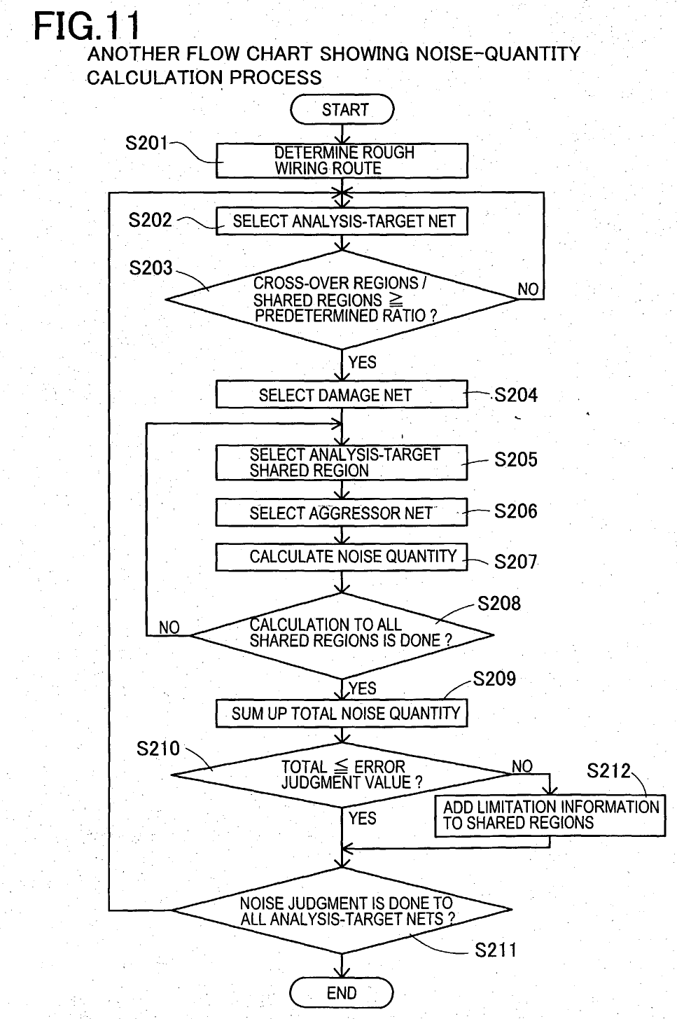

Alternatively, excess of noise quantity may be transferred to next process as the limitation information of this net as shown in FIG. 11 instead of correcting this rough wiring route. According to the method shown in FIG. 11, if the sum result of the crosstalk noise quantity is larger than a predetermined error judgment value (No in S210), the limitation information is attached to the target shared G-unit (S212). The flow chart shown in FIG. 11 is the same as FIG. 10 except the processing of this portion. According to this method, generation of error is avoided by placing wires taking into account the attached limitation information. For example, when wiring is actually conducted, upon actual placing of wires, the wiring interval in the shared G-unit supplied with the limitation information may be enlarged or the adjoining condition may be adjusted corresponding to a driving capacity in order to avoid the generation of error.

On the other hand if it is determined that the sum result does not exceed the error judgment value (Yes in S210), it can be said that there is no possibility that an error may occur about that victim net. The noise determination about this victim net is terminated and next, whether or not the noise determination about all analysis-target nets is terminated is determined (S211). If the noise determination is not terminated (No in S211), a next analysis-target net is selected (S202) and if it is selected as a victim net, noise determination is carried out (S203-S210). If checking on all the analysis-target nets is completed (Yes in S211), this processing is terminated.

As described in detail above, according to the wiring design method of this embodiment, the frame 100 is divided into four regions and the numbers of wirings crossing the borders are equalized. It is easy to count the numbers of the wirings crossing the borders and compare that number, making the determination for the equalization of the numbers easy and objective. Then, each divided region is further divided to four regions and the numbers of wirings crossing the borders are equalized. This procedure is repeated until the length of a side of the G-unit obtained by the division is lower than a predetermined value (about 10-20 grids). That is, at a rough wiring placing stage, a place which the wiring routes are congested is eliminated while the divided region is made finer gradually. Consequently, at a detailed wiring placing time, generation of wiring congestion region is avoided. Then, the rough wiring routes can be set up within the frame 100 as uniformly as possible.

Next, the noise quantity of each wiring route placed roughly is estimated using the equivalent model. If this estimated noise quantity exceeds the error judgment value, the rough wiring route is corrected. If a rough wiring in which the estimated noise quantities of all routes do not exceed the error judgment value is obtained, an actual wiring layout is created within a range of that rough wiring. Therefore, the noise quantity does not have to be calculated after the wiring layout is actually created. Upon determination of a wiring layout in the integrated circuit device, a wiring layout without such a problem as congestion of wirings can be determined effectively.

This embodiment is just an example of the present invention, but does not restrict the present invention. Therefore, the present invention may be improved or modified in various ways within a range not departing from the gist of the invention. For example, although, according to the above described embodiment, the wiring region is divided into four regions in order to determine the rough wiring route, the number of the divisions is not restricted to this, but the wiring region may be divided into six regions or nine regions. Further, although, according to the above-described embodiment, the numbers of the wirings crossing the borders dividing the regions are equalized, it is permissible to equalize the numbers of the wirings included in each divided region.

Although, according to the above-described embodiment, whether or not the noise quantity of a net should be calculated is determined using the ratio of the number of the shared G-units with respect to the number of the crossing over G-units, it is permissible to analyze all nets without any determination.

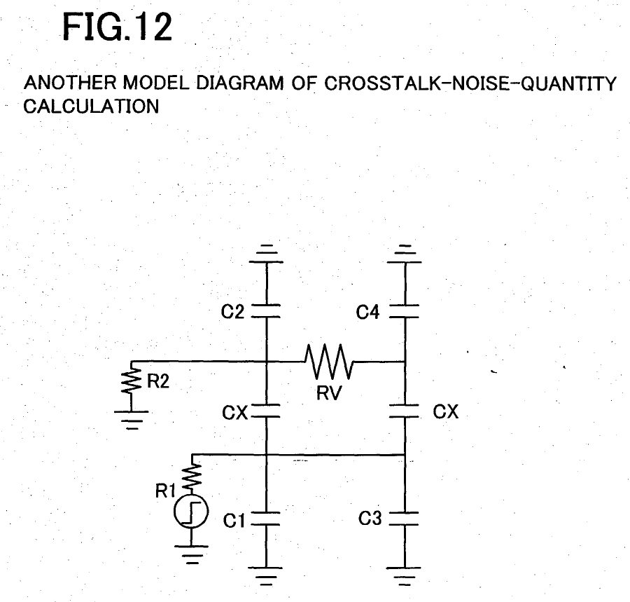

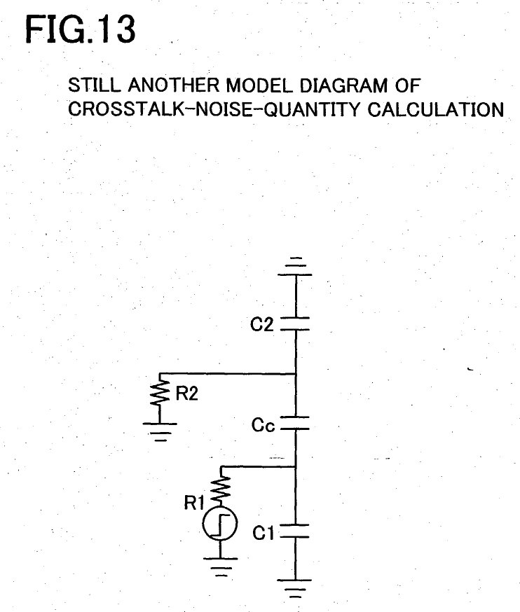

Further, according to the above-described embodiment, the π-Cx-π model shown in FIG. 8 is created as the equivalent model of the noise calculation simple circuit model. However, as the equivalent model, the ones shown in FIGS. 12 and 13 may be adopted.

What is claimed is:

1. A wiring design method for determining wiring routes between cells of an integrated circuit device, the wiring design method comprising:
region-divide step where a wiring-arrangement-target region is divided in both vertical and horizontal directions;
rough-arrange step where, divided regions for wiring arrangement is determined with respect to each of wirings out of the wiring-arrangement-target region divided in the region divide step; and
rearrange step where an alternative divided region for wiring arrangement is determined again in case wiring distribution among divided regions determined in the rough-arrange step is not uniform;
wherein wiring routes are determined within determined divided regions.

2. A wiring design method of an integrated circuit device according to claim 1, wherein, number of wirings that cross over boundaries of divided regions is counted with respect each boundary and in case inequality degree among count values is out of acceptable range, wiring arrangement is determined again in the rearrange step.

3. A wiring design method of an integrated circuit device according to claim 1, wherein the region-divide step, the rough-arrange step, and the rearrange step are repeated until size of divided regions are reduced to reach a predetermined value, and in region-divide step of second-time or thereafter, the divided regions are further divided in both vertical and horizontal directions.

4. A wiring design method of an integrated circuit device according to claim 2 further comprising:
noise-estimate step where a maximum value of crosstalk noises is estimated based on determined wiring arrangement; and
countermeasure step where crosstalk noises are reduced with respect to a wiring whose maximum value estimated at the noise-estimate step exceeds a predetermined value,
wherein the noise-estimate step and the countermeasure step are processed after the rearrange step.

5. A wiring design method for determining wiring routes between cells of an integrated circuit device, the wiring design method comprising:
region-divide step where a wiring-arrangement-target region is divided in both vertical and horizontal directions;
rough-arrange step where, divided regions for wiring arrangement is determined with respect to each of wirings out of the wiring-arrangement-target region divided in the region divide step;
noise-estimate step where a maximum value of crosstalk noises is estimated based on determined wiring arrangement; and
countermeasure step where crosstalk noises are reduced with respect to a wiring whose maximum value estimated at the noise predict step exceeds a predetermined value,
wherein wiring routes are determined within determined divided regions.

6. A wiring design method of integrated circuit device according to claim 5, wherein a maximum value of crosstalk noises is estimated with respect to a wiring such that occupancy rate of number of crossed-over divided regions shared with other wirings against total number of crossed-over divided regions is higher than a predetermined value in the noise-estimate step.

7. A wiring design method of integrated circuit device according to claim 5, wherein the noise-estimate step includes:
individual calculation step where a maximum value of crosstalk noises occurable to a target wiring is calculated for each crossed-over divided region shared with other wirings; and
sum-up step where maximum values calculated for all of crossed-over divided regions shared with other wirings with respect to the target wiring in the individual calculation step are summed up and a sum of the maximum values is regarded as a maximum value of crosstalk noises to occur to the target wiring.

8. A wiring design method of integrated circuit device according to claim 7, wherein there are performed following procedures for each of crossed-over divided regions shared with other wirings with respect to the target wiring in the individual calculation step:
a procedure that an aggressor wiring that generates and brings crosstalk noises to a target wiring is selected among wirings that share a divided region;
a procedure that a maximum value of crosstalk noises to be brought to the target wiring by a selected aggressor wiring is calculated; and
a procedure that a maximum value calculated is regarded as a maximum value of crosstalk noise to occur to the target wiring at a target divided region shared with other wirings.

9. A wiring design method of integrated circuit device according to claim 8, wherein among wirings that share a divided region with a target wiring, a wiring output-slew-rate of which is steepest is selected as aggressor wiring in the individual calculation step.

10. A wiring design method of integrated circuit device according to claim 8, wherein among wirings that share a divided region with a target wiring, a wiring that has a cell of highest output driving performance is selected as aggressor wiring in the individual calculation step.

11. A wiring design method of integrated circuit device according to claim 5, wherein a divided region on which a target wiring is arranged is changed to another in the countermeasure step.

12. A wiring design method of integrated circuit device according to claim 5, wherein, in the countermeasure step, limitation information is assigned to a target wiring, and when wiring routes are finally determined within a determined divided region, distance between the target wiring to which limitation information is assigned and other wirings that share the divided region with the target wiring is taken as wide as possible.

13. A wiring design system for determining wiring routes between cells of an integrated circuit device comprising:
region-divide unit for dividing a wiring-arrangement-target region in both vertical and horizontal directions;
rough-arrange unit for determining divided regions of the wiring-arrangement-target region on which each of wirings should be arranged; and
rearrange unit for determining an alternative divided region on which a wiring should be arranged in case wiring distribution among divided regions determined in the rough arrange step is not uniform;
wherein wiring routes are determined and arranged within determined divided regions.

14. A wiring design system for determining wiring routes between cells of an integrated circuit device comprising:
region-divide unit for dividing a wiring-arrangement-target region in both vertical and horizontal directions;
rough-arrange unit for determining a divided region of the wiring-arrangement-target region on which each of wirings should be arranged;
noise-estimate unit for estimating a maximum value of crosstalk noises based on determined wiring arrangement; and
countermeasure unit for reducing crosstalk noises with respect to a wiring whose maximum value estimated at the noise-estimate unit exceeds a predetermined value,
wherein wiring routes are determined and arranged within determined divided regions.

15. A computer program product used for executing wiring design of an integrated circuit device by a computer, the computer program product comprising:
a computer readable medium; and
a computer program stored on the computer readable medium, the computer program comprising:
region-divide step for dividing a wiring-arrangement-target region in both vertical and horizontal directions and assigning identification information to each of divided regions;
rough-arrange step for determining rough arrangement of each wiring defined in accordance with order that a wiring passes over divided regions divided in the region-divide step;
ununiformity-judge step for judging whether or not wiring distribution along with rough arrangement determined in the rough-arrange step has uniformity exceeding acceptable degree; and
rearrange step for determining again other way of rough arrangement of wirings in case wiring distribution is determined as exceeding the acceptable degree of ununiformity in the ununiformity-judge step.

16. A computer program product used for executing wiring design of an integrated circuit device by a computer according to claim 15, wherein the computer program further comprises size-judge step for judging whether or not size of a divided region is same as or smaller than a predetermined value and in case judged as not same as or smaller than the predetermined value, the computer program executes the region-divide step, rough-arrange step, ununiformity-judge step, and rearrange step, again.

17. A computer program product used for executing wiring design of an integrated circuit device by a computer, the computer program product comprising:
a computer readable medium; and
a computer program stored on the computer readable medium, the computer program comprising:
region-divide step for dividing a wiring-arrangement-target region in both vertical and horizontal directions and assigning identification information to each divided region;
rough-arrange step for determining rough arrangement of each wiring defined in accordance with order that a wiring passes over divided regions divided in the region-divide step;
noise-estimate step for estimating a maximum value of crosstalk noises based on determined wiring arrangement; and
countermeasure step for changing rough arrangement or assigning limitation information with respect to wiring whose maximum value estimated at the noise estimate step exceeds a predetermined value.
